(19) United States
(12) Patent Application Publication
(10) Pub. No.: US 2014/0326319 A1
(43) Pub. Date: Nov. 6, 2014

(54) Se OR S BASED THIN FILM SOLAR CELL AND METHOD FOR FABRICATING THE SAME

(71) Applicant: KOREA INSTITUTE OF SCIENCE AND TECHNOLOGY, Seoul (KR)

(72) Inventors: Won Mok KIM, Seoul (KR); Jin-soo KIM, Seoul (KR); Jeung-hyun JEONG, Seoul (KR); Jong-Keuk PARK, Seoul (KR); Young Joon BAIK, Seoul (KR)

(21) Appl. No.: 13/943,088

(22) Filed: Jul. 16, 2013

(30) Foreign Application Priority Data
May 2, 2013 (KR) 10-2013-0049174

(51) Int. Cl. H01L 31/0224

(52) U.S. Cl. CPC H01L 31/022483; H01L 31/022466
USPC 136/264; 438/95; 136/252

(57) ABSTRACT

The present disclosure relates to a Se or S based thin film solar cell and a method for fabricating the same, which may improve the structural and electrical characteristics of an upper transparent electrode layer by controlling a structure of a lower transparent electrode layer in a thin film solar cell having a Se or S based light absorption layer. In the Se or S based thin film solar cell having a light absorption layer and a front transparent electrode layer, the front transparent electrode layer comprises a lower transparent electrode layer and an upper transparent electrode layer, and the lower transparent electrode layer comprises an oxide-based thin film obtained by blending an impurity element into a mixed oxide in which Zn oxide and Mg oxide are mixed (also, referred to as an ‘impurity-doped Zn—Mg-based oxide thin film’).

### CROSS-REFERENCE TO RELATED APPLICATION

This application claims priority to Korean Patent Application No. 10-2013-0049174, filed on May 2, 2013, and all the benefits accruing therefrom under 35 U.S.C. §119, the contents of which in its entirety are herein incorporated by reference.

### BACKGROUND

1. Field

The present disclosure relates to a Se or S based thin film solar cell and a method for fabricating the same, and more particularly, to a Se or S based thin film solar cell and a method for fabricating the same, which may improve crystallinity and electric characteristics of an upper transparent electrode layer by controlling a structure of a lower transparent electrode layer in a thin film solar cell having a Se or S based light absorption layer.

2. Description of the Related Art

A Se or S based thin film solar cell such as CIGS (Cu(In₁₋ₓ,Gaₓ)(Se,S)₂) and CZTS (Cu₂ZnSn(Se,S)₄) is expected as a next-generation inexpensive high-efficient solar cell since it may exhibit high photoelectric transformation efficiency due to a high light absorption rate and excellent semiconductor characteristics (a GIGS solar cell exhibits photoelectric transformation efficiency of 20.3%-ZSW in German). Since the CIGS solar cell may be used as a high-efficient solar cell even on not only a transparent glass substrate but also a metal substrate made of stainless steel, titanium or the like and a flexible substrate such as a polyimide (PI) substrate, the CIGS solar cell may be produced at a low cost by means of a roll-to-roll process, may be installed at a low cost due to light weight and excellent durability, and may be applied in various fields as BIPV and various portable energy sources due to its flexibility.

FIG. 1 shows a most universal structure of a thin film solar cell 1 having a Se or S based light absorption layer. An opaque metal electrode layer 2 is provided on a substrate 1, a Se or S based p-type light absorption layer 3 is provided on the opaque metal electrode layer 2, and a sulfide-based n-type buffer layer 4 made of CdS or ZnS is provided on the light absorption layer 3. Front transparent electrode layers 5, 6 are provided on the buffer layer 4, and the front transparent electrode layers 5, 6 play a role of transmitting solar rays as much as possible so that the solar rays reaches the light absorption layer and a function of collecting and taking out carriers generated by the solar rays absorbed by the light absorption layer. In other words, front transparent electrode layers should have excellent transmission property with respect to visible rays and light in a near-infrared region and excellent electric conductivity.

Generally, in the thin film solar cell having a Se or S based light absorption layer, the front transparent electrode layers have a double-layer structure composed of a lower transparent electrode layer 5 and an upper transparent electrode layer 6 (U.S. Pat. No. 5,078,804 and US Unexamined Patent Publication No. 2005-109392). The lower transparent electrode layer 5 has semiconductor characteristics, but due to low electric resistivity, its necessity and role are still controversial. However, it has been reported that the lower transparent electrode layer 5 contributes to stability of a solar cell and enhances reproducibility in fabricating a module. This is because, in the case the upper transparent electrode layer 6 which is highly conductive due to large doping comes in direct contact with a buffer layer, the influence of defects such as a pin-hole probably existing in the light absorption layer increases, and the non-uniformity in the electric field of the upper transparent electrode layer 6 may cause local irregularity of the solar cell. Accordingly, in the thin film solar cell having a Se or S based light absorption layer presently used in the art, intrinsic ZnO (i-ZnO) with a relatively high electric resistance is formed on the buffer layer 4 as the lower transparent electrode layer 5. In addition, n-type ZnO doped with impurity elements such as Al, Ga, B, F, and H is formed on the lower transparent electrode layer 5 as the upper transparent electrode layer 6 (NREL internal report NREL/CP-520-46235, I. Repins, et al.). In other words, the double layer of i-ZnO/n-type ZnO is used as the front transparent electrode layers 5, 6.

Meanwhile, CdS material has been used the most as the n-type buffer layer 4. However, in order to avoid toxicity of Cd and decrease an absorption loss caused by a low photonic band-gap of the CdS material, a ZnS-based buffer layer having no toxicity and a large photonic band-gap is being actively studied. The buffer layer is generally deposited by means of chemical bath deposition (CBD). Since ZnS thin film fabricated in this way usually contains O and OH and generally expressed as Zn(S,O,OH) (Progress in Photovoltaics: Research and Applications, 17 (2009) 470-478, C. Hubert et al.). The photonic band-gap of the Zn(S,O,OH)-based buffer layer has an photonic band-gap greater than 3.3 eV which is an photonic band-gap of intrinsic ZnO (i-ZnO) used as a lower transparent electrode layer. Accordingly, it has been reported that an oxide mixed with ZnO and MgO instead of i-ZnO is to be used as the lower transparent electrode layer in order to lower an absorption loss caused at the lower transparent electrode layer and suitably maintain a band structure of a solar cell (Progress in Photovoltaics: Research and Applications, 17 (2009) 479-488, D. Hariskos et al.).

### RELATED LITERATURES

### Patent Literature

U.S. Pat. No. 5,078,804
US Unexamined Patent Publication No. 2005-0109392

### Non-Patent Literature

NREL internal report NREL/CP-520-46235, I. Repins et al.
Progress in Photovoltaics: Research and Applications, 17 (2009) 470-478, C. Hubert et al.
Progress in Photovoltaics: Research and Applications, 17 (2009) 479-488, D. Hariskos et al.

### SUMMARY

A ZnO-based oxide thin film used as a front transparent electrode layer is generally deposited by means of sputtering or chemical vapor deposition (CVD), and the sputtering method is most frequently used due to easiness in treatment of a large area and excellent electric characteristics.

The doped ZnO-based transparent conductive oxide thin film is known to have improved conductivity if a deposition temperature rises since the crystallinity and doping efficiency of the thin film are improved, similar to a general thin film. However, this is just a case of an optimized doping composition, and different tendencies may be exhibited with different compositions.

FIG. 2 shows the changes of specific resistivities obtained an Al-doped ZnO thin film (hereinafter, referred to as AZO, see ‘2-1’ in FIG. 2) with an optimized doping amount and a Ga-doped ZnO thin film (hereinafter, referred to as GZO, see ‘2-2’ in FIG. 2) as a function of deposition temperature. The thin films grown at low temperature exhibited relatively high specific resistivity due to defects and deteriorated crystallinity. The films deposited at temperature near 150° C. exhibited the lowest specific resistivity. With further increase in deposition temperature, the specific resistivity increased. The increase in the specific resistivity for films deposited at higher temperature is attributed to two reasons; (1) the formation of large amount of defects in ZnO may be probable due to the loss of Zn with high equilibrium vapor pressure, or (2) Al or Ga dopants may form oxide in the form of Al—O or Ga—O instead of serving as a doping element in Zn sites, which will cause the lowering of the carrier concentration and Hall mobility. In FIG. 2, it may be found that the AZO 2-1 and the GZO 2-2 have most excellent electric characteristics near 150° C. It has to be mentioned that, even in a ZnO-based thin film with an optimized doping amount, the temperature exhibiting optimized electric characteristics may vary depending on a deposition method or a deposition condition.

Referring to FIG. 2, in the case of the Ga-doped ZnO thin films 2-3 and 2-4 having a doping amount less than the optimized doping amount, as the deposition temperature rises, the specific resistivity decreases. However, in the thin film solar cell having a Se or S based light absorption layer, it is not favorable for the deposition temperature of the front transparent electrode layer to exceed the range of 150 to 200° C. Therefore, in the thin film solar cell having a Se or S based light absorption layer, it can be seen that the condition for forming a front transparent electrode layer with optimized electric characteristics is fabricating a ZnO thin film with an optimized doping composition at deposition temperature range from 150 to 200° C.

FIG. 3 shows the variations of specific resistivities of GZO films deposited at room temperature (3-1 and 3-2) and 150° C. (3-3 and 3-4) as a function of the thickness of the lower transparent electrode layer made of intrinsic ZnO (i-ZnO). The GZO films 3-1 and 3-3 are deposited directly on glass substrates, and the GZO films 3-2 and 3-4 are deposited on i-ZnO layer pre-coated on glass substrates using identical deposition condition to 3-1 and 3-3, respectively. First, if comparing the results at room temperature, the GZO thin films 3-1 deposited directly on the glass substrate and the GZO thin films 3-2 deposited on the i-ZnO layer exhibit very similar specific resistivities except for the case of the thickest i-ZnO layer. In the case of the thickest i-ZnO layer, the GZO thin film 3-2 deposited on the i-ZnO layer has specific resistivity slightly lower than the GZO thin film 3-1 deposited on the glass substrate. However, when the deposition is carried out at 150° C., it may be found that the specific resistivities of the GZO thin films 3-3 on the glass substrate are lower than those of the GZO thin films 3-4 deposited on the i-ZnO layer of any thickness. In addition, it may also be understood that, as the thickness of the i-ZnO layer increases, the specific resistivity of the GZO thin film deposited thereon increases.

FIG. 4 shows the variations of Hall mobility for the corresponding thin films shown in FIG. 3. In case of room temperature deposition, it can be seen that GZO thin films 4-1 deposited on the glass substrates and GZO thin films 4-2 deposited on i-ZnO layers have very similar Hall mobility. However, in case of deposition at 150° C., it may be found that GZO thin films 4-3 deposited on the glass substrate exhibit significantly higher Hall mobility than GZO thin films 4-4 deposited on the i-ZnO, and the difference increases as the thickness of i-ZnO increases.

Referring to the results of FIGS. 3 and 4, it can be seen that the doped ZnO thin films, which have optimized electrical properties, deposited on i-ZnO layer at 150 to 200° C. exhibit lower Hall mobility and higher specific resistivity than those deposited on the glass substrates at the corresponding deposition temperature.

The ZnO-based thin films generally have a hexagonal wurtzite structure. When deposited by sputtering, the films grow along a preferred orientation with (002) surface parallel to the substrate surface, frequently revealing strong (002) peak at around 34.4 degree in X-ray diffraction spectrum. In FIG. 5, the X-ray diffraction spectra of the (002) peaks obtained from the GZO thin films deposited on 46 nm thick i-ZnO layers at room temperature and 150° C. are compared with those of GZO films deposited on the glass substrates at corresponding temperatures. Referring to FIG. 5, in case of room temperature deposition, it can be seen that the X-ray diffraction peak of a GZO thin film 5-2 deposited on the i-ZnO layer is only slightly smaller than that of a GZO thin film 5-1 deposited on the glass substrate. In case of the deposition at 150° C., the GZO thin film 5-3 deposited on the glass substrate exhibits a very strong (002) peak intensity, indicating that the film possesses well developed crystallinity with (002) preferred orientation. On the other hand, the (002) peak intensity of the GZO thin film 5-4 deposited on the i-ZnO layer is not much different from those of the GZO thin films 5-1 and 5-2 deposited at room temperature, which shows that crystallinity of the GZO film deposited on i-ZnO layer is not improved in spite of being deposited at 150° C.

FIG. 6 shows the (002) peaks of an i-ZnO layer 6-1 and a GZO thin film 6-2 deposited at 150° C. on the glass substrate. Both i-ZnO layer 6-1 and GZO thin film 6-2 have a thickness of around 95 nm. Clearly, the (002) peak intensity of the GZO thin film 6-2 is far stronger than that of the i-ZnO layer 6-1. This is because the impurities doped in ZnO play a role of mineralizer or surfactant in promoting crystal growth. For this reason, if a doped ZnO thin film (for example, a GZO thin film) serving as an upper transparent electrode layer is grown on the i-ZnO layer serving as a lower transparent electrode layer with poor crystallinity, the crystallinity with (002) preferred orientation of the upper transparent electrode layer (the doped ZnO) is deteriorated due to the influence of poor crystallinity of the lower transparent electrode layer (i-ZnO) in comparison to the thin film grown on the glass substrate.

When the deposition temperature is low, atoms, molecules or ions sputtered from a target and deposited to the substrate do not have sufficient energy. The atoms, molecules or ions reaching the substrate are mostly deposited at the locations of arrival due to low ad-atom mobility. Therefore, the structure of the growing film is not affected significantly by the structure of the underneath layer or the substrate (for example, the glass substrate or i-ZnO). For this reason, the GZO thin films deposited on the glass substrate and i-ZnO layer at room temperature show almost similar structural characteristics (as shown in FIG. 5) and electrical characteristics (as shown in FIGS. 3 and 4) to each other. On the other hand, if the deposition is carried out at an elevated temperature, the thermal energy from the heated substrate provides the atoms, molecules or ions with sufficient ad-atom mobility for reaching the substrate. Accordingly, the crystalline structure of the growing thin film is significantly influenced by the structure of the underneath layer. Therefore, in case of deposition at 150° C., the (002) peak intensity of the GZO thin film grown on the i-ZnO layer is deteriorated due to the poor crystallinity of i-ZnO layer in comparison to that of the GZO thin film grown on the glass substrate. As shown in FIGS. 3 and 4, the poor crystallinity resulted in the low Hall mobility and the high specific resistivity for the GZO films deposited on i-ZnO layer at 150° C. in comparison to GZO films deposited on the glass substrate.

From the above results, it may be understood that the electrical properties of the upper transparent electrode layer are affected by the structural properties, and such structural properties of the upper transparent electrode layer is greatly affected by a lower structure where the upper transparent electrode layer grows, namely a structure of the lower transparent electrode layer.

As described in the ‘Description of the Related Art’ section above, a ZnS-based buffer layer having no toxicity and a large photonic band-gap is being actively studied in order to avoid toxicity of Cd and decrease an absorption loss caused by a low photonic band-gap of the CdS material. In addition, it has been reported that an oxide mixed with ZnO and MgO instead of i-ZnO is to be used as the lower transparent electrode layer in order to lower an absorption loss caused at the lower transparent electrode layer and suitably maintain a band structure of a solar cell.

FIG. 7 shows the changes of electrical conductivity (σ=1/ρ) and Hall mobility (μ) of GZO thin films formed on thin films in which i-ZnO and MgO are mixed, which serve as the lower transparent electrode layer, by using the ratios which were taken as the properties on the buffer layer to those on the bare glass substrate. In FIG. 7, 7-1 represents the change in the ratio of electrical conductivity (that is, σ_{on buffer}/σ_{on glass}), and 7-2 represents the change in the ratio of the corresponding Hall mobility (that is, μ_{on buffer}/μ_{on glass}) with respect to the change in the amount of Mg (Mg/(Zn+Mg), atom %) among metal components in the lower transparent electrode layer. Mg/(Zn+Mg) ratios of four samples shown in FIG. 7 are respectively 0, 9.9, 22.1 and 33.6% in an increasing order of Mg content. As shown in FIG. 7, if the amount of Mg is large, the electrical properties of the GZO thin film formed on the lower transparent electrode layer is similar to or superior to those of the GZO thin film deposited on the glass substrate. However, if the amount of Mg decreases, the electrical properties of the GZO thin films formed on the lower transparent electrode layer deteriorate when compared with those of the GZO thin films formed on the glass substrate. This is similar to the above case in which the structural and electrical characteristics of the upper transparent electrode layer are affected by poor crystallinity of the i-ZnO lower transparent electrode layer. In FIG. 8, the X-ray diffraction spectra of (002) peaks obtained from GZO thin films (8-2, 8-4, 8-6) deposited on the lower transparent electrode layers are compared with those (8-1, 8-3, 8-5) deposited on the bare glass substrate. FIGS. 8(a), 8(b) and 8(c) are the comparisons of XRD peaks when the composition ratios of Mg/(Zn+Mg) are 0% (namely, i-ZnO), 10% and 22%, respectively. As the composition ratio of Mg/(Zn+Mg) increases, (002) peaks 8-2, 8-4, 8-6 of the GZO thin films grown on the lower transparent electrode layer tend to gradually increase. The improvement of crystallinity with increasing the composition ratio of Mg/(Zn+Mg) seems to be in good agreement with the change of electrical properties with respect to composition as shown in FIG. 7. However, in all three cases, the (002) peak intensities of GZO films deposited on the buffer electrode layer are weaker than those of the GZO thin film deposited on the glass substrate. Therefore, in order to obtain a good upper transparent electrode in wide range of Mg/(Zn+Mg) composition, it is necessary to fabricate the lower transparent electrode layer with a good structural crystallinity with strong (002) peak intensity even in low Mg/(Zn+Mg) composition.

The present disclosure is designed in consideration to the above, and therefore it is an object of the present disclosure to provide a Se or S based thin film solar cell and a method for fabricating the same, which may improve structural and electrical characteristics of an upper transparent electrode layer by controlling a structure of a lower transparent electrode layer in a thin film solar cell having a Se or S based light absorption layer.

In one aspect, there is provided a Se or S based thin film solar cell having a light absorption layer and a front transparent electrode layer, wherein the front transparent electrode layer comprises a lower transparent electrode layer and an upper transparent electrode layer, and wherein the lower transparent electrode layer comprises an oxide-based thin film obtained by blending an impurity element to a mixed oxide in which Zn oxide and Mg oxide are mixed (hereinafter, referred to as an ‘impurity-doped Zn—Mg-based oxide thin film’).

The impurity-doped Zn—Mg-based oxide thin film may have a photonic band-gap of 3.2 to 4.5 eV, and the impurity-doped Zn—Mg-based oxide thin film may have a an atomic ratio of Mg/(Zn+Mg) of 45 atom % or less. In addition, the impurity-doped Zn—Mg-based oxide thin film may have an atomic ratio of (Zn+Mg)/(Zn+Mg+impurity element) of 90 to 99 atom %.

The impurity element doped to the impurity-doped Zn—Mg-based oxide thin film may be at least one selected from the group consisting of group-III elements, group-IV elements, transition metals, glass metals, halogen elements, and their mixtures. The group-III elements may include B, Al, Ga and In, the group-IV elements may include Si, Ge and Sn, the transition metals may include Ti, V, Cr, Mn, Fe, Co, Ni, Cu, Zr, Nb, Mo, Ag and Cd, the halogen elements may include F, and the glass metals may include Sb.

A photonic band-gap of the impurity-doped Zn—Mg-based oxide thin film may increase when Mg content increases, and the upper transparent electrode layer may be a ZnO-based thin film.

In another aspect, there is provided a method for fabricating a Se or S based thin film solar cell having a light absorption layer, a lower transparent electrode layer and an upper transparent electrode layer, which includes: forming an oxide-based thin film obtained by blending an impurity element to a mixed oxide in which Zn oxide and Mg oxide are mixed (hereinafter, referred to as an ‘impurity-doped Zn—Mg-based oxide thin film’); and forming a crystalline oxide-based thin film on the lower transparent electrode layer.

The Se or S based thin film solar cell and the method for fabricating the same give the following effects.

Since the oxide-based thin film obtained by blending impurities with a mixed oxide mainly containing Zn oxide and Mg oxide is used as the lower transparent electrode layer, the crystalline structure with (002) preferred orientation of the upper transparent electrode layer may be enhanced, and accordingly electrical characteristics of the upper transparent electrode layer may be improved. In addition, since the light absorption in a short-wavelength region can be improved in comparison to an existing i-ZnO layer, the photoelectric transformation efficiency of the thin film solar cell may be increased.

Moreover, the photonic band-gap of the lower transparent electrode layer may be controlled by changing the content of, as in the case of the mixed oxide mainly containing Zn oxide and Mg oxide, and therefore the absorption edge may be selectively adjusted.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is a cross-sectional view showing a conventional Se or S based thin film solar cell;

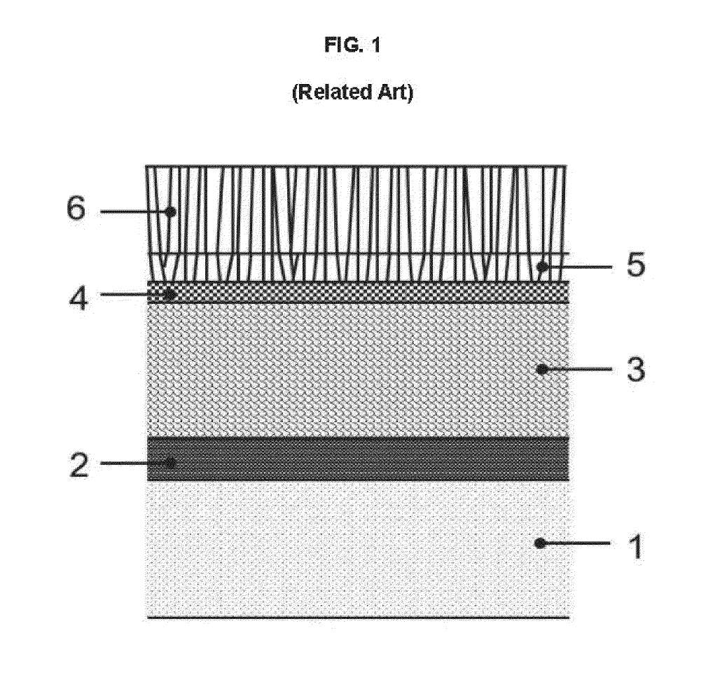

FIG. 2 is a graph showing the changes of specific resistivities with respect to a deposition temperature of Al-doped ZnO thin films and Ga-doped ZnO thin films;

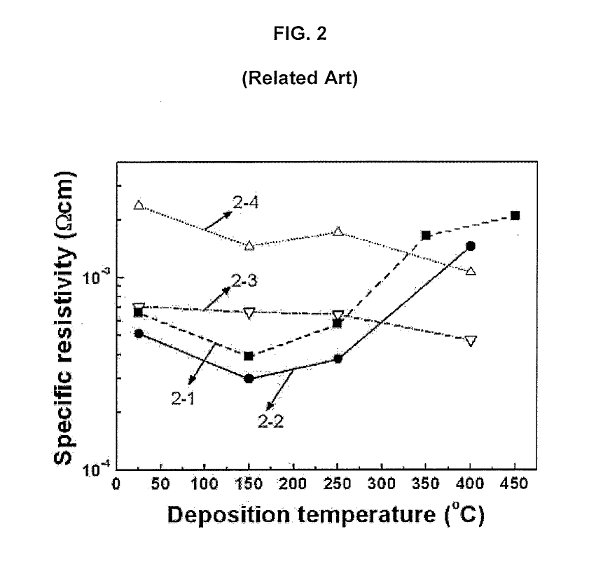

FIG. 3 is a graph showing the variations of the specific resistivity of GZO thin films deposited on glass substrates and i-ZnO layers grown on glass substrates at room temperature and 150° C., where the specific resistivity is plotted as a function of the thickness of the i-ZnO layer;

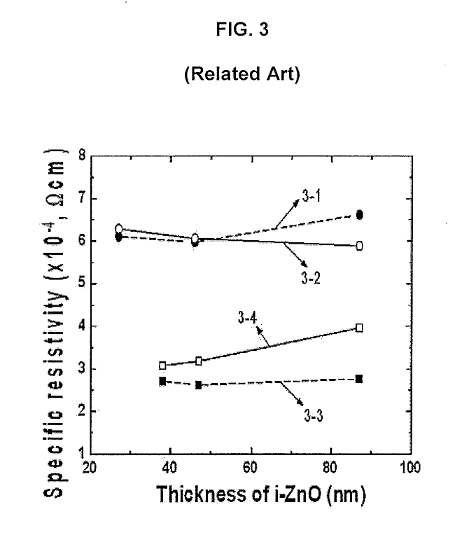

FIG. 4 is a graph showing the corresponding variations in Hall mobility of the GZO thin films shown in FIG. 3;

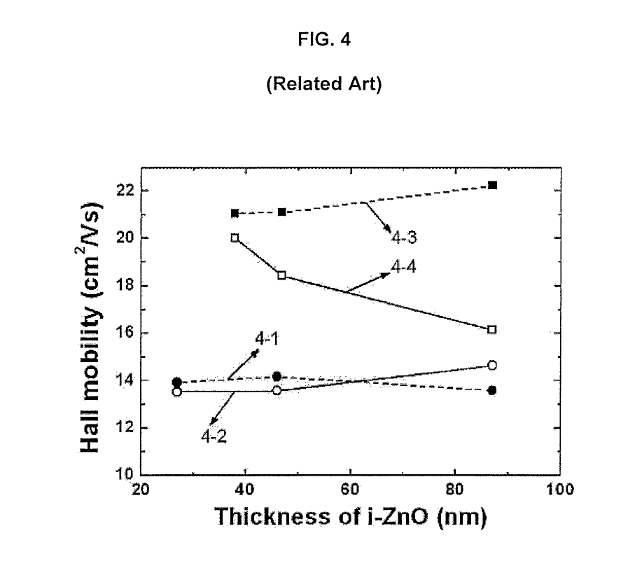

FIG. 5 shows the X-ray diffraction spectra of the (002) peaks obtained from the GZO thin films deposited at room temperature and 150° C. in the case the i-ZnO layer has a thickness of about 46 nm in the results of FIGS. 3 and 4;

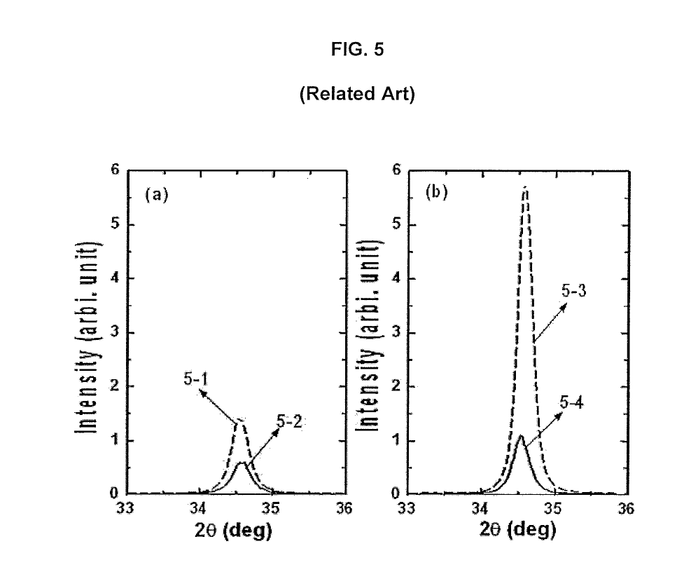

FIG. 6 shows the comparison of (002) peak profiles obtained from X-ray diffraction analysis for an i-ZnO layer 6-1 and a GZO thin film 6-2 with a similar thickness, which are deposited on the glass substrate at 150° C.;

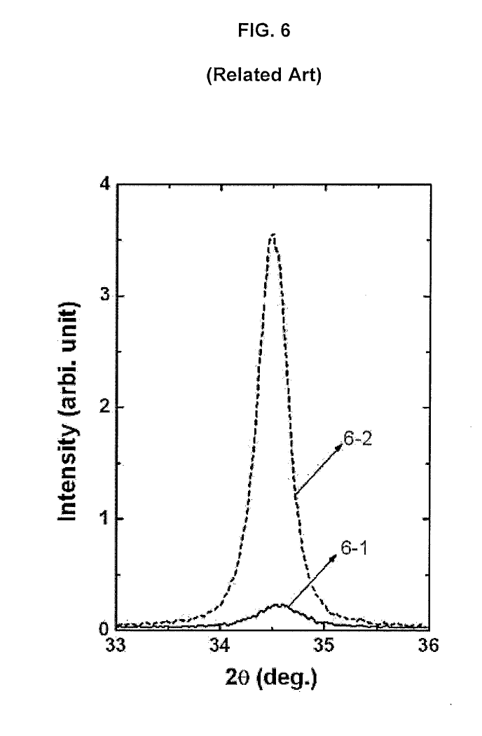

FIG. 7 shows the changes of electric conductivity (σ=1/ρ) and Hall mobility (μ) of GZO thin films by using the ratios, which were taken as the properties on mixed oxide thin films composed of Zn oxide and Mg oxide to those on the bare glass substrates, as a function of Mg composition ratio;

FIG. 8 comparatively shows the X-ray diffraction spectra of the (002) peaks obtained from the GZO thin films grown on mixed oxide thin films of ZnO—MgO and bare glass substrates whose electrical properties are shown in FIG. 7;

FIG. 9 is a cross-sectional view showing a Se or S based thin film solar cell according to an embodiment of the present disclosure;

FIG. 10a shows the X-ray diffraction spectra of the (002) peaks obtained from the mixed oxide thin films made of Zn oxide and Mg oxide with varying Mg composition ratio, and FIG. 10b shows the X-ray diffraction spectra of the (002) peaks obtained from the oxide-based thin films prepared by blending Ge as an impurity element with mixed oxides mainly containing Zn oxide and Mg oxide;

FIG. 11 comparatively shows light transmittance spectra of mixed oxide thin films 11-1, 11-3 made of Zn oxide and Mg oxide and oxide-based thin films 11-2, 11-4 obtained by blending Ga as an impurity element to a mixed oxide mainly containing Zn oxide and Mg oxide;

FIG. 12 shows the changes in the photonic band-gaps of mixed oxide thin films 12-1 composed of Zn oxide and Mg oxide and oxide-based thin films 12-2 obtained by blending Ga as an impurity element to a mixed oxide mainly containing Zn oxide and Mg oxide as a function of composition ratio of Mg;

FIG. 13a shows the changes in the ratios of electric conductivity 13-2 (σ_{on buffer}/σ_{on glass}) of GZO thin films, for which Ga-blended ZnO—MgO mixed oxide thin films are used as the lower transparent electrode layer, are compared with those 13-1 of GZO thin films, for which ZnO—MgO mixed oxide thin films are used as the lower transparent electrode layer, as a function of the change in the amount of Mg (Mg/(Zn+Mg+Ga), atom %) among metal components in the lower transparent electrode layer, and FIG. 13b shows the changes in the ratios of Hall mobility 13-4 and 13-3 corresponding to the ratios 13-2 and 13-1 shown in FIG. 13a; and

FIG. 14 shows the comparison between the (002) peak intensities 14-2, 14-4 obtained from X-ray diffraction analysis for the GZO thin films grown on Ga-blended ZnO—MgO mixed oxide thin films and the (002) peak intensities 14-1, 14-3 of the GZO thin films deposited on the glass substrate.

[Detailed Description of Main Elements]

| | |
|---|---|
| 1: substrate | 2: rear electrode |
| 3: light absorption layer | 4: buffer layer |

5′: amorphous lower transparent electrode layer
6: upper transparent electrode layer

### DETAILED DESCRIPTION

The present disclosure relates to a front transparent electrode layer of a so-called Se or S based thin film solar cell, which uses Se or S based material as a light absorption layer.

The front transparent electrode layer may be implemented as a double-layer structure composed of an upper transparent electrode layer and a lower transparent electrode layer, and the upper transparent electrode layer plays a role of collecting carriers generated by photoelectric transformation.

Generally, in a Se or S based thin film solar cell using a ZnO-based thin film doped with impurities as an upper transparent electrode, in order to improve carrier collecting efficiency of the upper transparent electrode layer, an electrical conductivity characteristic, namely a specific resistivity, should be excellent, and the specific resistivity has close relationship with the structural properties of the thin film. In other words, for ZnO-based thin films having the same free carrier concentration, if the crystallinity of the thin film improves, factors disturbing the movement of free carrier at grain boundaries and crystallographic defects decreases, which increases Hall mobility and thus improves the specific resistivity of the thin film. Therefore, in order to improve the carrier collecting efficiency of the upper transparent electrode layer, the crystallinity of the upper transparent electrode layer should be enhanced. However, since the upper transparent electrode layer is formed on the lower transparent electrode layer, the structural properties of the upper transparent electrode layer is affected by the structure of the lower transparent electrode layer.

In the present disclosure, a ZnO-based thin film doped with impurity elements is applied as the upper transparent electrode layer, and a Zn—Mg-based oxide thin film obtained by blending impurity elements to a mixed oxide in which Zn oxide and Mg oxide are mixed is applied as the lower transparent electrode layer for improving crystalline structure with (002) preferred orientation of the upper transparent electrode layer.

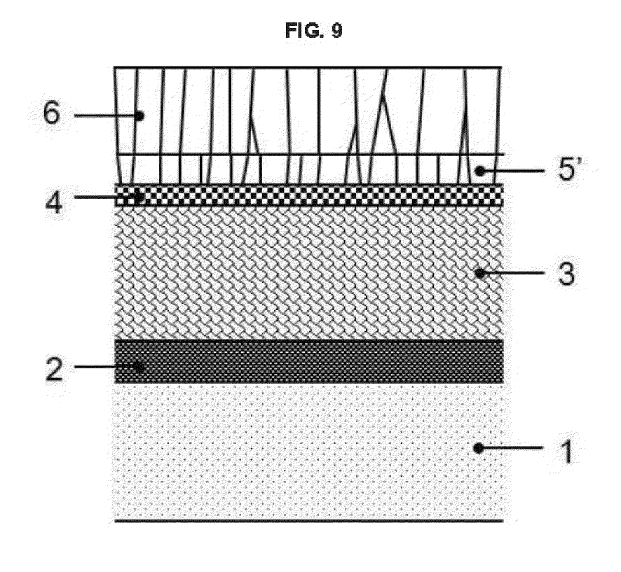

Looking into the overall configuration of the Se or S based thin film solar cell to which the upper transparent electrode layer and the lower transparent electrode layer 5 according to the present disclosure are applied (see FIG. 9), a rear electrode 2, a light absorption layer 3, a buffer layer 4, a lower transparent electrode layer 5′, and an upper transparent electrode layer 6 are sequentially formed on a substrate 1. It is worth mentioning that components other than the lower transparent electrode layer 5′ and the upper transparent electrode layer 6 may be selectively modified if necessary. The rear electrode 2 is made of opaque metallic material such as molybdenum (Mo), the light absorption layer 3 is made of Se or S based material such as Cu(In₁₋ₓ,Gaₓ)(Se,S)₂ (CIGS) and Cu₂ZnSn(Se,S)₄ (CZTS), and the buffer layer 4 may be made of material such as CdS and ZnS. In the Se or S based thin film solar cell as described above, the light absorption layer 3 and the buffer layer 4 make a p-n junction to induce photoelectric transformation, and carriers (electrons and holes) generated by the photoelectric transformation are respectively collected by a front transparent electrode layer and a rear electrode 2 to generate electricity.

In order to ensure high light transparency, suppress recombination of carriers and enhance carrier collecting efficiency, both the upper transparent electrode layer and the lower transparent electrode layer should have a photonic band-gap over a certain level. In addition, the upper transparent electrode layer should have low specific resistivity, and the lower transparent electrode layer should have relatively high specific resistivity. Moreover, in order to reduce an absorption loss, both the upper transparent electrode layer and the lower transparent electrode layer should have excellent light transparency.

In the present disclosure, a Zn—Mg-based oxide thin film doped with impurities is applied as the lower transparent electrode layer, and a ZnO-based crystalline thin film doped with impurity elements is applied as the upper transparent electrode layer. The Zn—Mg-based oxide thin film doped with impurities is used as the lower transparent electrode layer in order to ensure a good crystalline structure with (002) preferred orientation of the upper transparent electrode layer over a certain level when the upper transparent electrode layer is deposited. A ZnO thin film doped with impurities may be used as the upper transparent electrode layer in order to stably ensure a free charge concentration over 10²⁰ cm⁻³.

As described in the “Description of the Related Art” section and the “Summary” section above, since the intrinsic ZnO (i-ZnO) used as the lower transparent electrode layer has a relatively high specific resistance and a low free charge concentration, the photonic band-gap has a value near 3.3 eV. Therefore, if the material of the buffer layer is changed, it is difficult to suitably cope with an absorption loss and a band structure. In the present disclosure, since the lower transparent electrode layer includes Zn oxide and Mg oxide and the composition of Mg is controlled, the photonic band-gap of the lower transparent electrode layer may be selectively adjusted. Further, since an impurity element is blended into a mixed oxide of Zn oxide and Mg oxide, when the upper transparent electrode layer is formed, the structural properties of the upper transparent electrode layer may be improved. The impurity element blended into the mixed oxide of Zn oxide and Mg oxide plays a role of mineralizer or surfactant to help crystal growth of the thin film.

The lower transparent electrode layer uses an oxide-based thin film obtained by blending impurity elements to a mixed oxide of Zn oxide and Mg oxide, namely ‘a impurity-doped Zn—Mg-based oxide thin film’, and satisfies a condition of an oxide semiconductor in which the photonic band-gap is 3.2 to 4.5 eV.

The impurity elements doped in the impurity-doped Zn—Mg-based oxide thin film may be at least one of group-III elements, group-IV elements, transition metals, and their mixtures. The group-Ill elements include B, Al, Ga and In, the group-IV elements include Si, Ge and Sn, and the transition metals include Ti, V, Cr, Mn, Fe, Co, Ni, Cu, Zr, Nb, Mo, Ag and Cd. In addition to the elements above, a halogen element, F, and a glass metal, Sb, may be doped to the impurity-doped Zn—Mg-based oxide thin film.

Specifically, the impurity-doped Zn—Mg-based oxide thin film may have an atom % of Mg/(Zn+Mg) of 45% or below with respect to Zn and Mg which are metal elements other than oxygen and impurity elements. If the atomic ratio (atom %) of Mg/(Zn+Mg) exceeds 45%, the crystal structure of the lower transparent electrode layer starts deviating from a ZnO crystal structure of hexagonal system, and cubic MgO crystals start appearing, which does not help the improvement of (002) peak intensity of the ZnO-based upper transparent electrode layer which grows thereon.

Meanwhile, in the impurity-doped Zn—Mg-based oxide thin film, a composition ratio of both Zn and Mg, among elements except for oxygen, namely an atom % of (Zn+Mg)/(Zn+Mg+impurity elements), may be 90% or above and 99% or below. If the concentration of impurities is small, it is not easy to improve crystallinity of the lower transparent electrode layer. If the concentration is too high, compounds of the impurity elements appears, which disturbs crystallinity of the lower transparent electrode layer.

Even though the lower transparent electrode layer contains a small amount of impurity elements in addition to Zn oxide and Mg oxide, a photonic band-gap may be selectively controlled by adjusting Mg content, similar to the mixed oxide thin film of Zn oxide and Mg oxide. Referring to examples of the present disclosure below, it may be found that the photonic band-gap of the lower transparent electrode layer may be controlled in various ways by adjusting the relative composition of Zn and Mg. If the Mg content increases, the photonic band-gap increases and the light transparency in the short-wavelength region is improved. Both the upper transparent electrode layer and the lower transparent electrode layer may be formed by means of sputtering and vapor deposition.

Hereinafter, the characteristics of the lower transparent electrode layer applied to the Se or S based thin film solar cell according to the present disclosure will be described by means of examples.

### Example 1

A pure ZnO target and a MgO target have been co-sputtered to prepare a thin film made of a mixed oxide of ZnO and MgO, and a Ga-doped ZnO target (GZO) and a pure MgO target have been co-sputtered to prepare a thin film made of a mixed oxide of ZnO—MgO blended with Ga. After that, structural characteristics of the thin films have been observed. Table 1 shows a Mg atomic ratio (Mg/(Zn+Mg+Ga, atom %) of the prepared thin films. S1 series are samples free from MgO, S2 series have Mg composition ratios of about 10%, S3 series have Mg composition ratios of about 22%, and S4 series have Mg composition ratios of about 33%. In this way, ZnO—MgO mixture thin films have been prepared to be compared with the Ga-blended ZnO—MgO mixed oxide thin films at similar Mg composition ratios. Table 1 shows Ga composition ratios of the Ga-blended ZnO—MgO mixed oxide thin films.

TABLE 1
Atomic Ratio of each Thin Film

| | ZnO—MgO | Ga-blended ZnO—MgO | |
|---|---|---|---|
| | Mg/(Zn + Mg) | Mg/(Zn + Mg + Ga) | Ga/(Zn + Mg + Ga) |
| Samples | (atom %) | (atom %) | (atom %) |
| S1 | 0 | 0 | 5.3 |
| S2 | 9.9 | 10.4 | 4.7 |
| S3 | 21.9 | 22.4 | 4.1 |
| S4 | 33.6 | 33.0 | 3.5 |

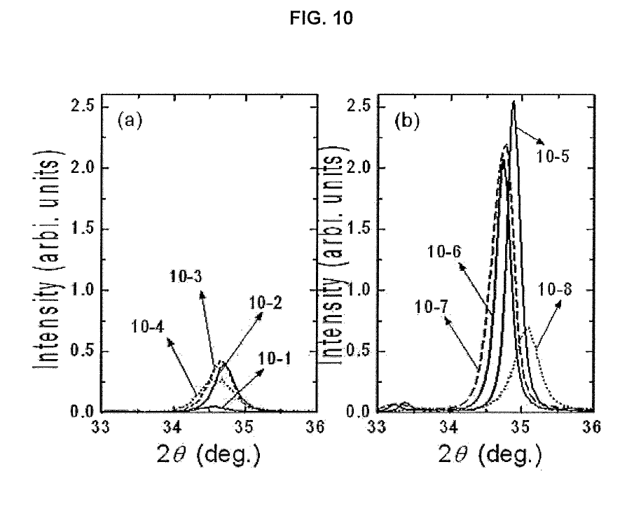

FIG. 10a shows the X-ray diffraction spectra of the (002) peaks obtained from ZnO—MgO mixed oxide thin films, and FIG. 10b shows the X-ray diffraction spectra of the (002) peaks obtained from Ga-blended ZnO—MgO mixed oxide thin films. In FIG. 10, 10-1 and 10-5 represent S1-series samples, 10-2 and 10-6 represent S2-series samples, 10-3 and 10-7 represent S3-series samples, and 10-4 and 10-8 represent S4-series samples. As shown in FIG. 10a, it may be found that if the Mg composition ratio increases, (002) peak intensity of the ZnO—MgO-based mixed oxide thin film becomes stronger, and if the Mg composition ratio increases further, (002) peak intensity decreases again. For the Ga-blended ZnO—MgO mixed oxide thin films, the tendency with respect to the Mg composition ratio is somewhat different from the ZnO—MgO mixed oxide thin films. In other words, it may be found that (002) peak intensity is strongest when Mg is absent, and if the Mg composition ratio increases, (002) peak intensity gradually decreases. However, if FIGS. 10a and 10b are compared, it may be found that the Ga-blended ZnO—MgO mixed oxide thin films have stronger (002) peak intensities than the ZnO—MgO mixed oxide thin films in all composition ranges, and therefore the crystallinity is more excellent. For reference, the y axes of FIGS. 10a and 10b have the same scale.

From the above result, it may be understood that in case of the Ga-blended ZnO—MgO mixed oxide thin films, Ga plays a role of promoting crystallization of the mixed oxide thin film.

### Example 2

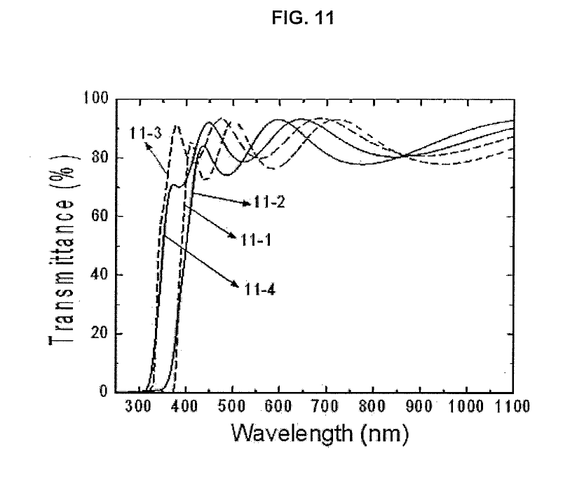

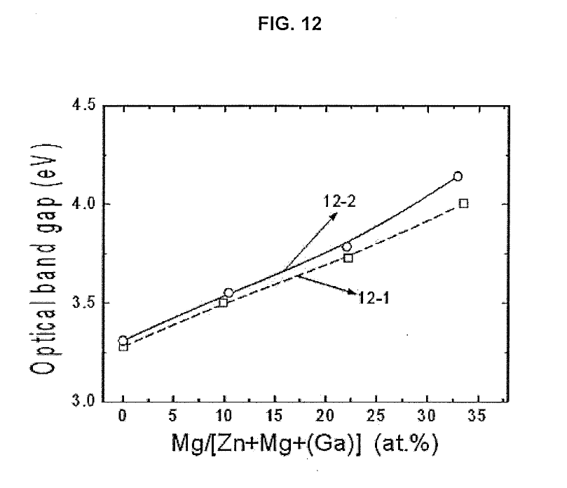

Optical characteristics of the ZnO—MgO mixed oxide thin films and the Ga-blended ZnO—MgO mixed oxide thin films, prepared in Example 1, have been analyzed. FIG. 11 shows light transmittance spectrums, obtained from the S1-series mixed oxide thin films 11-1, 11-3 and the S3-series mixed oxide thin films 11-2, 11-4 in Table 1. It may be found that both the Ga-blended ZnO—MgO mixed oxide thin films 11-2, 11-4 and the ZnO—MgO-based mixed oxide thin films 11-1, 11-3 have excellent light transparency. It can be seen that the films with similar Mg content exhibit similar fundamental absorption edges which are located at ultraviolet region where the light transparency rapidly decreases. In addition, it may be found that the absorption edges of the S3-series thin films are substantially shifted toward a short wavelength when compared with those of the S1-series thin films. FIG. 12 shows the change of photonic band-gaps, obtained from thin films made of the ZnO—MgO mixed oxide and thin films made of the Ga-blended ZnO—MgO mixed oxide, shown in Table 1, as a function of the change of a Mg composition ratio. In both the ZnO—MgO mixed oxide thin films 12-1 and the Ga-blended ZnO—MgO mixed oxide thin films 12-2, the photonic band-gap increases with increasing Mg composition ratio. Therefore, it may be understood that the photonic band-gap of the mixed oxide thin films doped with impurity elements may be easily controlled by simply adjusting Mg content, as in the case of the ZnO—MgO-based mixed oxide thin films.

### Example 3

Electric characteristics of GZO samples obtained by using the thin films made of a ZnO—MgO mixed oxide and the thin films made of a Ga-blended ZnO—MgO mixed oxide as the lower transparent electrode layer have been compared with those of GZO thin films deposited on glass substrate under the same condition.

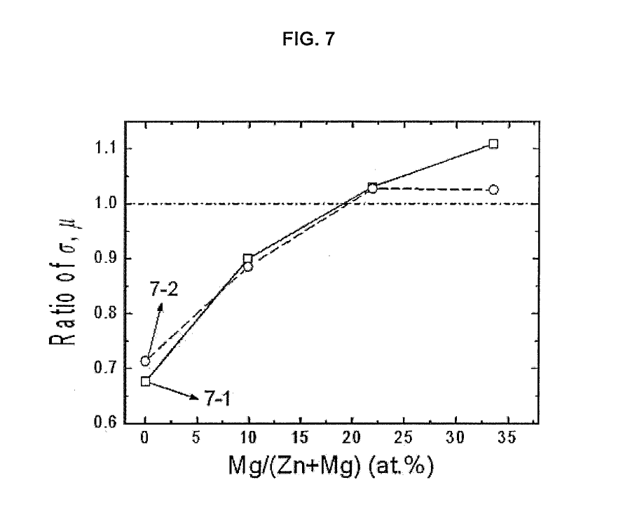

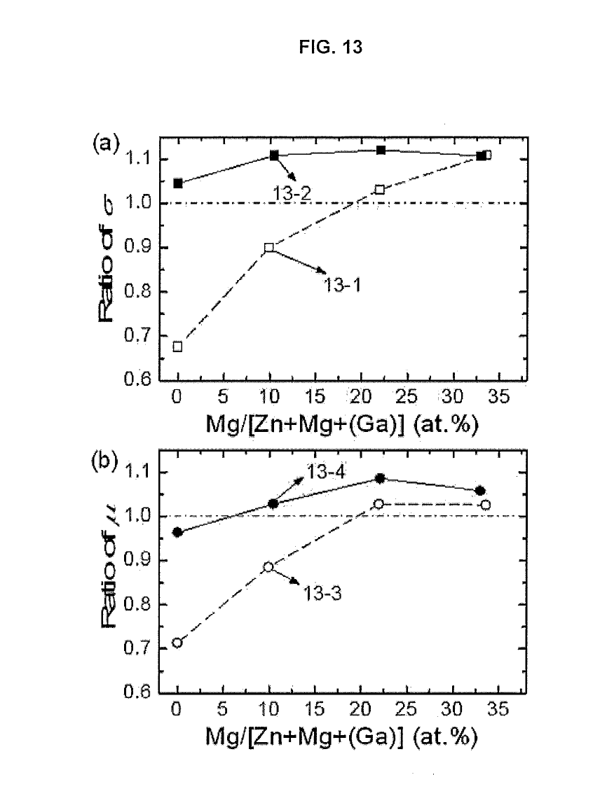

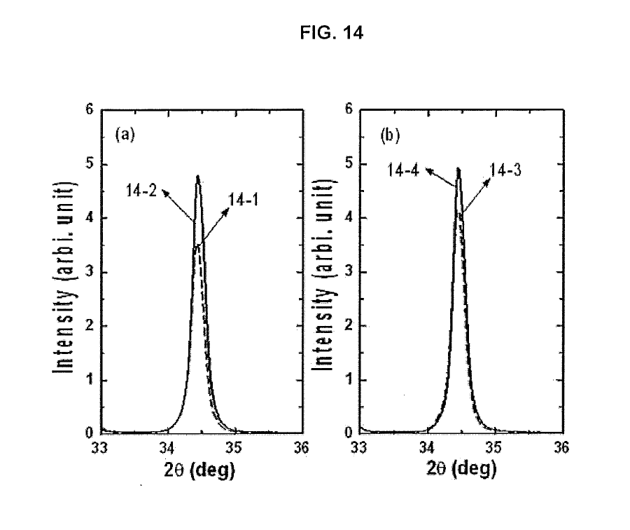

In FIG. 13, the changes in the ratios of electric conductivity 13-2 (σ_{on buffer}/σ_{on glass}) and Hal mobility 13-4 (μ_{on buffer}/μ_{on glass}) of GZO thin films, for which Ga-blended ZnO—MgO mixed oxide thin films are used as the lower transparent electrode layer, are compared with those of GZO thin films, for which ZnO—MgO mixed oxide thin films are used as the lower transparent electrode layer, as a function of the change in the amount of Mg (Mg/(Zn+Mg+Ga), atom %) among metal components in the lower transparent electrode layer. In FIG. 13, 13-1 and 13-3 represent the ratios of electric conductivity and Hall mobility in case of using the ZnO—MgO-based mixed oxide thin films as the lower transparent electrode layer, which are the same graphs as 7-1 and 7-2 shown in FIG. 7, and they are depicted again in FIG. 13 for comparison. From FIG. 13, it may be understood that the GZO thin films grown on Ga-blended ZnO—MgO mixed oxide thin films as the lower transparent electrode layer exhibit excellent electric conductivity and Hall mobility when compared with the GZO thin films grown on ZnO—MgO-based mixed oxide thin films as the lower transparent electrode layer, in all Mg composition ratios. The GZO thin films formed on ZnO—MgO-based mixed oxide thin films as the lower transparent electrode layer give much inferior electric characteristic in comparison to the GZO thin films deposited on the glass substrate when the Mg composition ratio is low. However, the GZO thin films formed on Ga-blended ZnO—MgO mixed oxide thin films as the lower transparent electrode layer give excellent electric conductivity in comparison to the GZO thin films deposited on the glass substrate. In particular, it may be found that in all Mg composition ratios tested, the GZO thin films deposited on Ga-blended ZnO—MgO mixed oxide thin films as the lower transparent electrode layer show excellent Hall mobility in comparison to the GZO thin films formed on ZnO—MgO-based mixed oxide thin films as the lower transparent electrode layer, which may be more clearly understood from the X-ray diffraction characteristic depicted in FIG. 14.

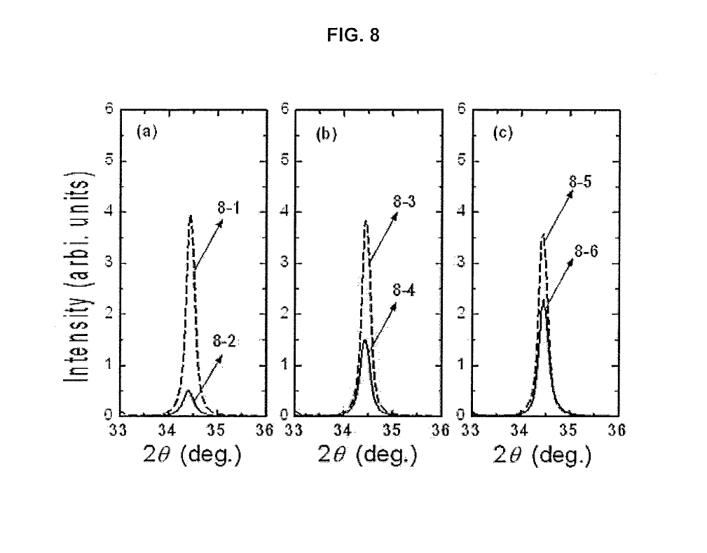

In FIG. 14, the X-ray diffraction spectra of the (002) peaks obtained from the GZO thin films (14-2, 14-4) deposited on the lower transparent electrode layers made of Ga-blended ZnO—MgO mixed oxide thin films are compared with those (14-1, 14-3) deposited on the bare glass substrate. The Mg composition ratios shown in FIGS. 14a and 14b are S2 and S3 series, which is comparable to the X-ray diffraction results of the GZO thin films (S2 and S3 series) using ZnO—MgO-based mixed oxide thin films as the lower transparent electrode layer as shown in FIGS. 8b and 8c. As shown in FIG. 14, (002) peak intensities (intensity) of the GZO thin films deposited on Ga-blended ZnO—MgO mixed oxide thin films are greater than those of the GZO thin films grown on the glass substrate. This is clearly in contrast with the result shown in FIGS. 8b and 8c, in which (002) peak intensities of the GZO thin films grown on ZnO—MgO-based mixed oxide thin films are much weaker than those of the GZO thin films grown on the glass substrate.

What is claimed is:

1. A Se or S based thin film solar cell having a light absorption layer and a front transparent electrode layer,
wherein the front transparent electrode layer comprises a lower transparent electrode layer and an upper transparent electrode layer, and
wherein the lower transparent electrode layer comprises an oxide-based thin film obtained by blending an impurity element to a mixed oxide in which Zn oxide and Mg oxide are mixed.

2. The Se or S based thin film solar cell according to claim 1, wherein the oxide-based thin film has a photonic band-gap of 3.2 to 4.5 eV.

3. The Se or S based thin film solar cell according to claim 1, wherein the oxide-based thin film has an atomic ratio of Mg/(Zn+Mg) of 45 atom % or less.

4. The Se or S based thin film solar cell according to claim 1, wherein the oxide-based thin film has an atomic ratio of (Zn+Mg)/(Zn+Mg+impurity element) of 90 to 99 atom %.

5. The Se or S based thin film solar cell according to claim 1, wherein the impurity element doped to the oxide-based thin film is at least one selected from the group consisting of group-III elements, group-IV elements, transition metals, glass metals, halogen elements, and their mixtures.

6. The Se or S based thin film solar cell according to claim 5, wherein the group-III elements include B, Al, Ga and In, the group-IV elements include Si, Ge and Sn, the transition metals include Ti, V, Cr, Mn, Fe, Co, Ni, Cu, Zr, Nb, Mo, Ag and Cd, the halogen elements include F, and the glass metals include Sb.

7. The Se or S based thin film solar cell according to claim 1, wherein a photonic band-gap of the oxide-based thin film increases as a Mg composition ratio increases.

8. The Se or S based thin film solar cell according to claim 1, wherein the upper transparent electrode layer is a ZnO-based thin film.

9. A method for fabricating a Se or S based thin film solar cell having a light absorption layer, a lower transparent electrode layer and an upper transparent electrode layer, the method comprising:
forming an oxide-based thin film obtained by blending an impurity element to a mixed oxide in which Zn oxide and Mg oxide are mixed; and
forming a crystalline oxide-based thin film on the lower transparent electrode layer.

10. The method for fabricating a Se or S based thin film solar cell according to claim 9, wherein the oxide-based thin film has a photonic band-gap of 3.2 to 4.5 eV.

11. The method for fabricating a Se or S based thin film solar cell according to claim 9, wherein the oxide-based thin film has an atomic ratio of Mg/(Zn+Mg) of 45 atom % or less.

12. The method for fabricating a Se or S based thin film solar cell according to claim 9, wherein the oxide-based thin film has an atomic ratio of (Zn+Mg)/(Zn+Mg+impurity element) of 90 to 99 atom %.

13. The method for fabricating a Se or S based thin film solar cell according to claim 9, wherein the impurity element doped to the oxide-based thin film is at least one selected from the group consisting of group-III elements, group-IV elements, transition metals, glass metals, halogen elements, and their mixtures.

14. The method for fabricating a Se or S based thin film solar cell according to claim 13, wherein the group-Ill elements include B, Al, Ga and In, the group-IV elements include Si, Ge and Sn, the transition metals include Ti, V, Cr, Mn, Fe, Co, Ni, Cu, Zr, Nb, Mo, Ag and Cd, the halogen elements include F, and the glass metals include Sb.

15. The method for fabricating a Se or S based thin film solar cell according to claim 9, wherein a photonic band-gap of the oxide-based thin film is adjusted by controlling a Mg composition ratio, and the photonic band-gap of the oxide-based thin film increases when the Mg composition ratio increases.

16. The method for fabricating a Se or S based thin film solar cell according to claim 9, wherein the upper transparent electrode layer is a ZnO-based thin film.
